(19) United States
(12) Patent Application Publication
(10) Pub. No.: US 2012/0108040 A1
(43) Pub. Date: May 3, 2012

(54) VAPORIZING POLYMER SPRAY DEPOSITION SYSTEM

(75) Inventors: Ching-Yu Chang, Yuansun Village (TW); Kuei-Liang Lu, Hsinchu City (TW); Ming-Feng Shieh, Yongkang City (TW)

(73) Assignee: TAIWAN SEMICONDUCTOR MANUFACTURING COMPANY, LTD., Hsin-Chu (TW)

(21) Appl. No.: 12/916,704

(22) Filed: Nov. 1, 2010

(51) Int. Cl. H01L 21/20; B05C 15/00; B05B 1/00; B05C 5/00

(52) U.S. Cl. 438/509; 118/300; 118/58; 257/E21.09

(57) ABSTRACT

A vaporizing spray deposition device for forming a thin film includes a processing chamber, a fluid line, and a spray head coupled to the fluid line proximate the processing chamber. The fluid line is configured to transfer a polymer fluid and solvent mixture to the spray head. The spray head is configured to receive the polymer fluid and solvent mixture and to atomize the polymer fluid and solvent mixture to emit it in a substantially vaporized form to be deposited on a surface and thereby forming a thin film of the polymer on the surface after evaporation of the solvent. In an embodiment, the vaporizing spray deposition device may include a heating device to perform a hard bake process on the polymer. In an embodiment, the vaporizing spray deposition device may be configured to provide a post deposition solvent spray trim process to the thin film polymer.

### BACKGROUND

The present disclosure relates generally semiconductor device fabrication and, more particularly, to a system for thin film formation on a semiconductor device using a vaporizing polymer spray deposition system.

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs. For these advances to be realized, similar developments in IC processing and manufacturing are needed. In the course of IC evolution, functional density (i.e., the number of interconnected devices per chip area) has generally increased while geometry size (i.e., the smallest component that can be created using a fabrication process) has decreased.

However, there are challenges to implementing such smaller and smaller features and processes in semiconductor fabrication. For example, in the course of fabricating semiconductor devices, a one or more patterned hard mask features may be formed on the device. An etching process may be used to form the pattern features. Such etching process may cause sharp inside corners in the features, which may reduce device etching performance.

One may fill-in the sharp corners by adding a photoresist/conformal coating layer to the device. Traditionally the coating is added by dropping a large volume of liquid photoresist/conformal coating on the device and spinning the device wafer to spread the liquid coating. This process cannot be performed in a traditional CMOS processing chamber. In addition, this process forms an uneven coating, such as a thin coating in high step places and a thick coating in the low places, such as between raised features on the device. Thus, the spin-on coating process generally fails to achieve a uniform high-step coverage polymer thin film. Another problem found with conventional coating systems include having a high-temperature CVD deposition process where there may be contamination problems if the structure wafer is coated with a photoresist film. As should be understood, conventional spin-on coating systems can not achieve a substantially uniform polymer type thin film deposition on semiconductor device wafers.

Thus, an improved a system for thin film formation on a semiconductor device using a vaporizing polymer spray deposition system.

### BRIEF DESCRIPTION OF THE DRAWINGS

FIG. 1 is a flow chart of an embodiment of a method of forming a thin film layer on a wafer.

FIG. 2 illustrates a cross-sectional view of an embodiment of a vaporizing spray deposition device corresponding to steps of the method of FIG. 1.

FIG. 2a illustrates a perspective view of an embodiment of a vaporizing spray deposition device corresponding to steps of the method of FIG. 1.

FIG. 3 illustrates a cross-sectional view of an embodiment of a semiconductor wafer and a hard mask layer having various raised features.

FIGS. 4 and 5 are cross-sectional views of an embodiment of the vaporizing spray deposition device of FIG. 2 and an embodiment of the semiconductor wafer hard mask layers of FIG. 3 at different stages of forming a thin polymer film thereon.

FIGS. 6 and 7 are top views of different embodiments of hard mask features and cavities therein having sharp corners in the features filled-in with a thin film coating layer.

### DETAILED DESCRIPTION

The present disclosure relates generally to semiconductor fabrication and more specifically to a vaporizing polymer spray deposition system and method for forming a thin film on a semiconductor device wafer. It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

In contrast to conventional chemical-vapor deposition (CVD) and spin-on coating systems, the present disclosure provides systems to vaporize a polymer fluid and then deposit the vaporized fluid on semiconductor wafers. Using this system, a very thin and substantially uniform polymer film may be formed to cover substantially all of the coated side of the structure. In other words, embodiments of the present disclosure provide systems and methods for forming a substantially uniform thin film on topographical semiconductor devices/wafers using a vaporizing/atomizing spray deposition system. Essentially, embodiments of the present disclosure use vaporized polymer fluids to spray on semiconductor wafers to form a uniform, thin polymer film, whereas conventional coating systems apply the coating as a large drop of the liquid and spin the device to spread the liquid.

As should be understood, a benefit of the vaporizing/atomizing spray deposition system is that it fills-in sharp internal corners on high-stepped, raised features, such as raised hard mask features, on the semiconductor wafer, which are not filled using the conventional systems. Another benefit includes resolving conventional problems known in the art with high-temperature thin film deposition on resisted wafers.

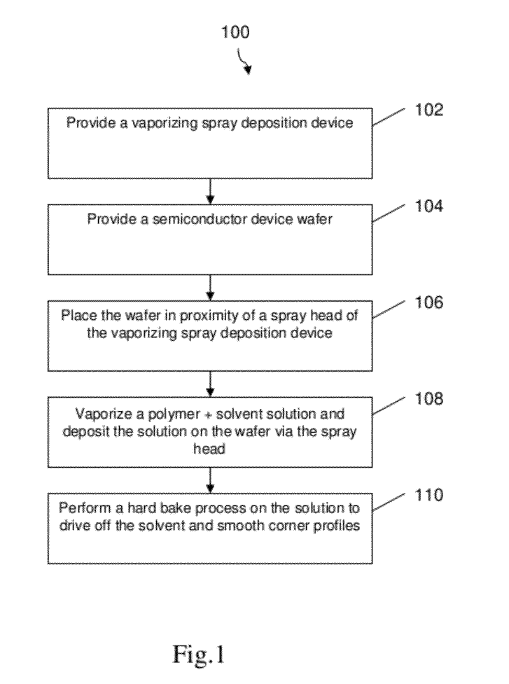

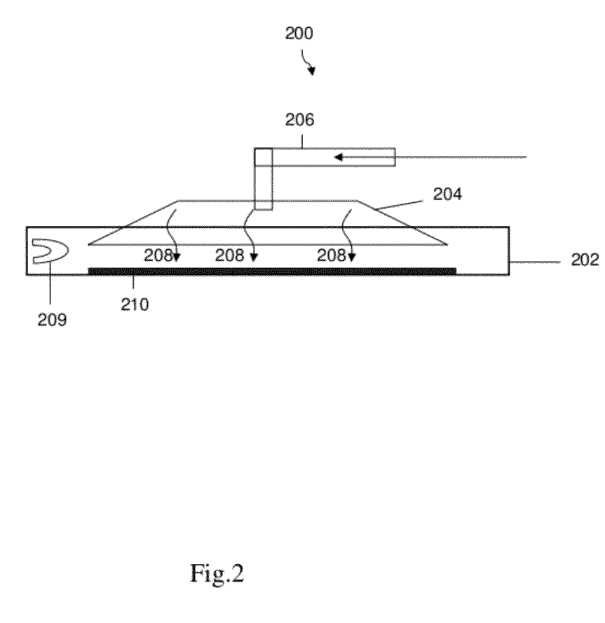

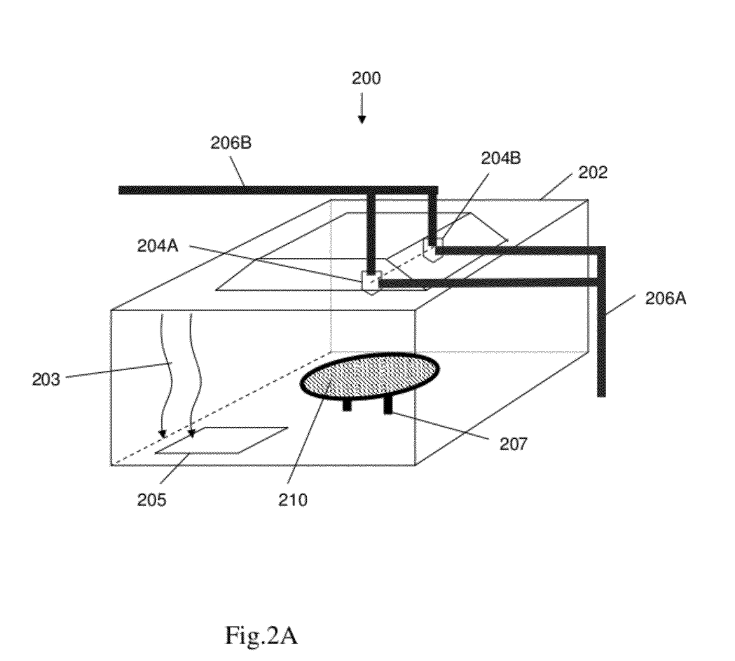

FIG. 1 illustrates a flow chart of an embodiment of a method 100 of forming a thin film layer on a wafer, such as a semiconductor device wafer 210. This method 100 is described herein with respect to the devices shown in FIGS. 2-7. The method 100 begins at block 102 where a spray deposition device is provided.

FIG. 2 illustrates a cross-sectional view of an embodiment of a spray deposition device 200 configured to operate corresponding to steps of the method 100. In an embodiment, the spray deposition device 200 is a vaporizing spray deposition system that atomizes a conformal coating fluid, such as a polymer/solvent solution, over a surface, such as a semiconductor wafer 210, that is to be coated. The spray device 200 includes a process chamber 202, a spray head 204, and a fluid line 206. In an embodiment, the process chamber 202 includes a heating device 209.

The process chamber 202, in one embodiment, is a closed-bottom container having a base and sidewalls extending upward from base toward the spray head around a perimeter of the base. Thus, the process chamber 202 is configured to hold and support one or more semiconductor devices/wafers and to catch a portion of the fluid overspray from the spray head 204. The process chamber 202 may be formed from a material substantially impervious to the polymer and solvent mixture vaporized by the spray head 204. In an alternative embodiment, the process chamber 202 may be a processing chamber typical of one or more CMOS processes.

The spray head 204 receives the fluid to be vaporized via the fluid line 206. The fluid line receives the transmitted fluid from a holding tank (not shown). In an embodiment, the fluid is supplied to the spray head heated and/or under pressure, thereby allowing the spray head 204 to receive the fluid mixture, vaporize/atomize the fluid, and emit the vaporized fluid toward the target surface in the process chamber 202. Both the spray head 204 and the fluid line 206 may be formed from a material substantially impervious to the polymer and solvent mixture vaporized by the spray head 204.

FIG. 2A illustrates a perspective view of another embodiment of a vaporizing spray deposition device 200 corresponding to steps of the method of FIG. 1. This embodiment includes a process chamber 202, a plurality of spray heads 204A and 204B, and a plurality of fluid lines 206A and 206B, which respectively provide polymer/solvent solution and high pressure N₂/air to the spray heads 204A and 204B. The pressure of the N₂/air may be varied to aid in the vaporization of the fluid mixture. The process chamber 202 may include a fan, blower or other device (not shown) to provide a down flow of air or other gas 203 (e.g., N₂) in the chamber 202 and out an exhaust vent 205 to aid in the spray process 100. The process chamber 202 also includes a wafer holder 207 for holding the wafer 210 firmly in the process chamber 202.

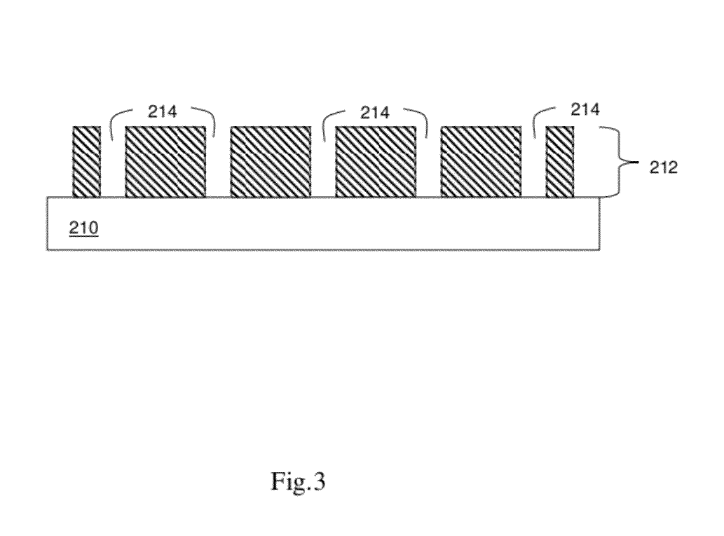

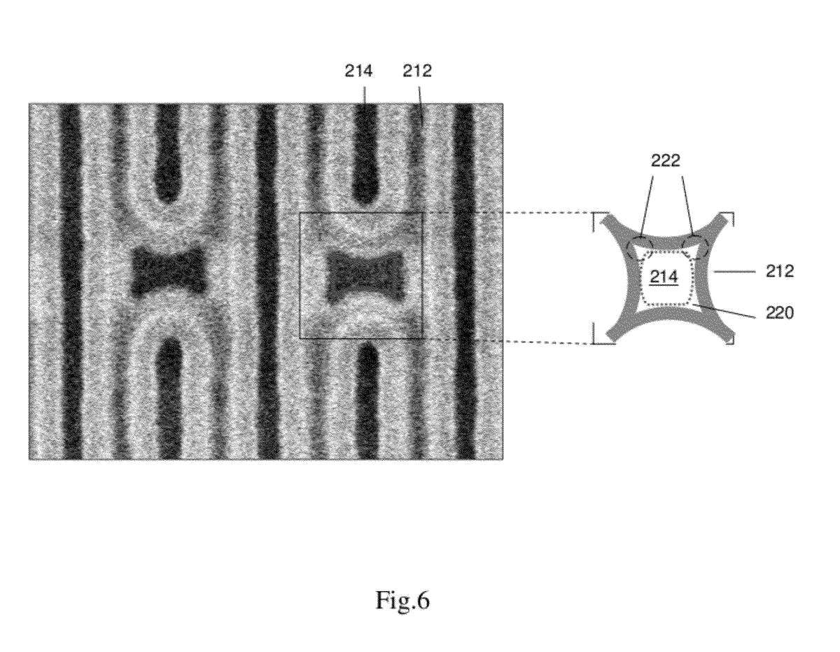

The method 100 then proceeds to block 104 where a semiconductor device wafer 210 is provided. The method 100 forms a thin coating on any surface, however a semiconductor device wafer 210 is discussed in this example. FIG. 3 illustrates a cross-sectional view of an embodiment of a semiconductor wafer having a hard mask layer 212, that is patterned to have various raised features therein. Though described herein as a hard mask layer 212, the method 100 is applicable to forming a polymer layer on any portion of a substrate, including any patterned layer. The hard mask features 212 have open cavities 214 between the features 212. Because of the very small dimensions involved in the pattern, the etching process that is used to pattern the hard mask layer 212 may form small, sharp interior corners between various features 212, when viewed in a top view (not shown here, see FIG. 6, discussed below). In an embodiment, the wafer 210 includes one or more layers (e.g., underlying layer 212) of Si, SiO₂, polysilicon, dielectric, and/or other materials to be etched. In an embodiment, the hard mask layer 212 includes SiO2, SiN, SiON, and/or other suitable materials. In another embodiment, the wafer layer 210 may include a second layer of hard mask, such as SiO2, SiN, SiON, TiN, and or other hard mask materials, wherein both layers are formed on other semiconductor device layers (not shown). If both layers are hard mask layers, they may be formed of different materials to provide etching selectivity for use of the hard mask 212. In alternative embodiments, the wafer 210 may include semiconductor features, such as a source, a drain, a gate, an isolation feature, and other semiconductor features. In other words, the wafer 210 may include any layer or material that is to be etched using a patterned layer, such as the hard mask layer 212, as a pattern for the etching process.

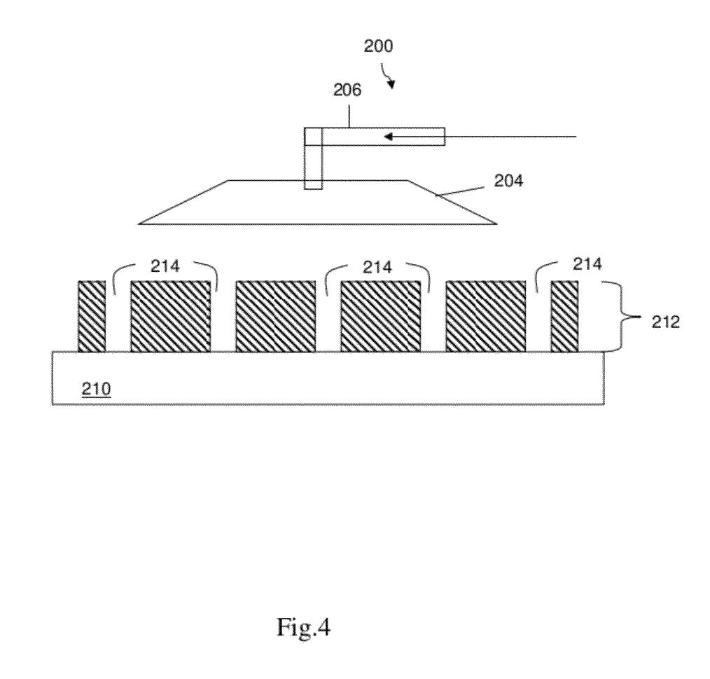

The method 100 proceeds next to block 106 where the wafer 210 is placed in proximity of the spray head 204, such as in the process chamber 202. FIG. 4 is a cross-sectional view of the wafer 210 placed in the proximity of the vaporizing spray deposition device 200.

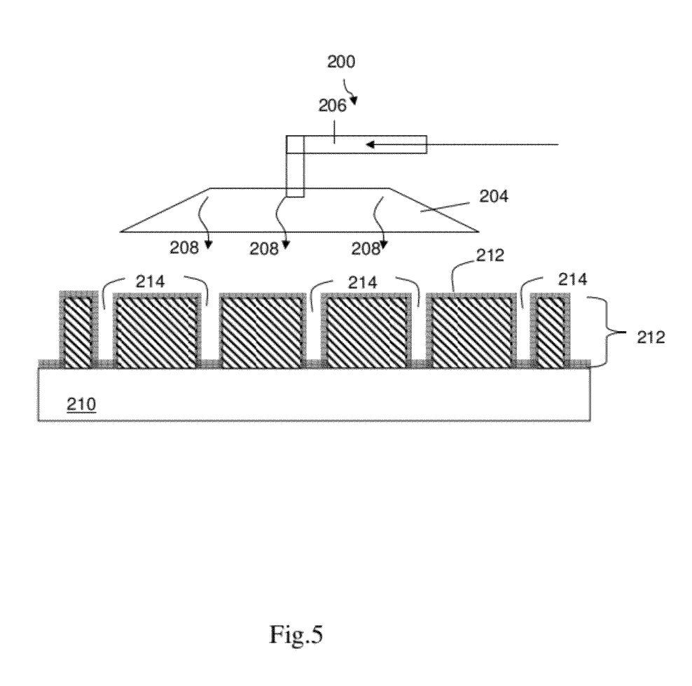

After the wafer 210 is placed in proximity of the spray head 204, the method 100 proceeds to block 108 where the spray head 204 receives the polymer/solvent mixture, vaporizes the mixture, and sprays/emits the vaporized mixture 208 toward the wafer 210 to form a thin film layer 220 on the wafer 210 (See FIG. 5). Using the polymer vapor 208 causes the thin film 220 to be formed to a substantially uniform thickness on the hard mask features 212, along the sidewalls of the cavities 214 and on the wafer 210 in the cavities 214. For example, the thin film layer 220 may be formed to have a height of less than 100 Angstrom. However, other heights of thin film 220 may be formed. In an embodiment, the diluted polymer/solvent solution may be a resist solvent. Exemplary compositions of the solvent solution include propylene glycol monomethyl ether (PEMG), Propylene glycol monomethyl ether acetate (PEMGA), cyclehexanol, ethyl lactate, and combinations thereof. The system may have a photo resist viscosity centipoises (cp) range from approximately 0.5 cp to approximately 2.5 cp. Here 1 cp=1 m Pa·s=0.001 (kg·m⁻¹·s⁻¹). In one embodiment, the polymer to solvent ratio is 0.1% to 10%.

The vaporizing spray deposition device 200 may have a deposition rate range of approximately 1 Angstrom per second to approximately 5 Angstrom per second. However, other deposition rates may be used. In an embodiment, the spray head 204 may vaporize the polymer/solvent fluid to have a droplet size range less than approximately 25 micrometers. After the deposition of the polymer layer 220, an optional solvent spray trim process may be performed on the polymer layer 220 to decrease the thickness of the polymer layer 220 at one or more regions.

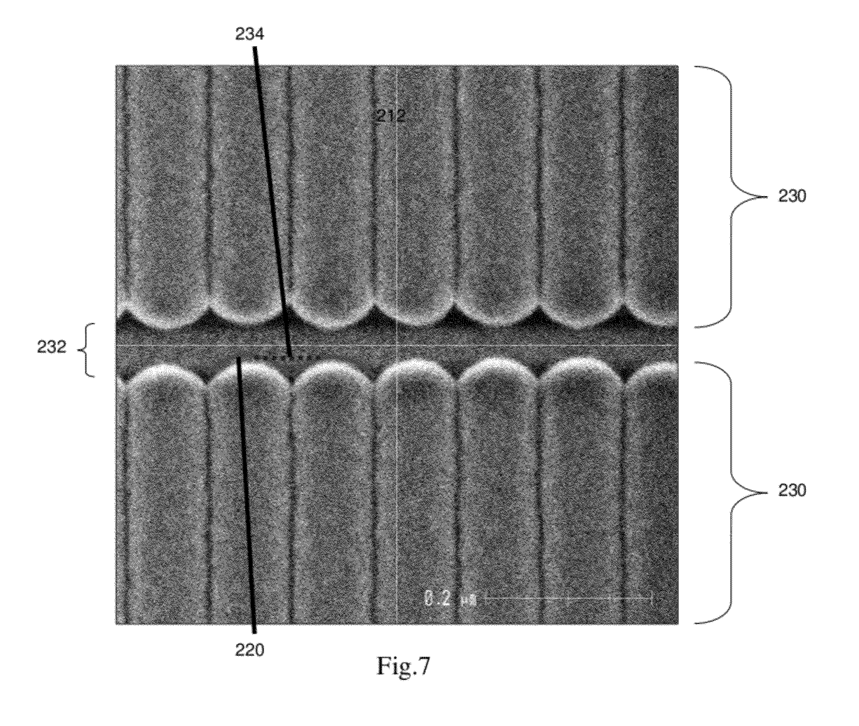

In an embodiment, the fluid is a polymer/solvent mixture. Thus, as the solvent evaporates, what remains is the layer of the polymer 220 on the wafer 210. Evaporation of the solvent may occur naturally when exposed to the atmosphere. In addition, a heating process may be performed on the polymer 220 to accelerate the evaporation of the solvent. Accordingly, the method 100 may proceed to block 110 where a hard bake process is performed on the polymer 220 to drive off the solvent. In addition, the hard bake process allows the polymer layer 220 to smooth out, thereby filling in the sharp interior angles between the features hard mask features 212, as shown in FIGS. 6 and 7. The hard bake process may be performed using the heating element 209 in the process chamber 202. In another embodiment, the hard bake process may be performed in a separate heating chamber. In an embodiment, the hard bake process may be performed at a temperature range of approximately 100 C to approximately 200 C. A specific example performs the hard bake process at a temperature range of approximately 130 C to approximately 150 C. The hard bake heating process may be performed for a time period ranging from one second to approximately 60 seconds. For example, one hard bake process performs the hard bake for a time period of approximately 20 seconds. However, it should be understood that other temperatures and other times may be used for the systems and methods of the present disclosure.

FIGS. 6 and 7 are top views of different embodiments of hard mask features 212, 230 and cavities 214, 232 having sharp corners 222, 234, which are filled in with the polymer layer 220 and the hard bake process of the present disclosure.

As described above, the spray coated polymer film may be formed on any patterned feature on a semiconductor substrate. In an embodiment, a process for forming a thin film on a semiconductor device may include using a Multiple Edge Enabled Patterning (MEEP) process, which uses spacer patterning technology to get end-to-end spacer film patterns merged. The spacer patterning technique is referred to as a “pitch-halving” process, and is described in more detail in patent application Ser. No. 12/370,152, filed on Feb. 12, 2009, and was published on Aug. 12, 2010, U.S. Publication Number 2010/0203734A1. Thereafter, the spacer oxide film roof is opened, and a vaporized polymer fluid is spray coated to provide a very thin film on the spacer oxide film. Then, a hard bake process may be performed to the polymer film to fill tiny voids in feature interior corners. A bottom hard mask film may be etched to smooth out the interior corners. Other embodiments may use a low temperature and/or room temperature atomic layer deposition (ALD) tool to deposit an ALD-oxide or an ALD SiN film, and other embodiments may use a two mask patterning process.

As should be understood from the foregoing, an embodiment of a vaporizing spray deposition device for forming a thin film includes a processing chamber, a fluid line, and a spray head coupled to the fluid line proximate the processing chamber. The fluid line is configured to transfer a polymer fluid and solvent mixture to the spray head. The spray head is configured to receive the polymer fluid and solvent mixture and to atomize the polymer fluid and solvent mixture to emit it in a substantially vaporized form to be deposited on a surface and thereby forming a thin film of the polymer on the surface after evaporation of the solvent.

In another embodiment provided herein, a photoresist spray deposition system includes a processing chamber, a fluid line, a spray head coupled to the fluid line proximate the processing chamber, and a heating device in the processing chamber. The a fluid line is configured to transfer a photoresist fluid spray head is configured to receive the photoresist fluid from the fluid line and atomize the photoresist fluid to emit it in a substantially vaporized form. The heating device is configured to provide a hard bake process to a semiconductor wafer receiving the photoresist fluid.

In yet another embodiment, the present disclosure provides a method of applying a thin film to a semiconductor wafer surface. The method includes providing a vaporizing spray deposition system and providing a semiconductor device wafer. The method further includes placing the semiconductor device wafer in proximity of an atomizing spray head on the vaporizing spray deposition system. Additionally, the method includes atomizing a polymer/solvent solution toward the semiconductor device wafer, thereby depositing the solution on the semiconductor device wafer.

The vaporizing deposition systems and methods described herein provide many advantages over conventional systems, a few of which include the following:
providing a smooth polymer surface on a semiconductor device due to polymer cohesion that inherently fills traditional tiny polymer surface voids;
improving traditional line edge/width roughness;
improving traditional pinched peak space in MEEP process;
providing a substantially uniform conformal resist thickness available for implant processing;
lower cost processing when compared to atomic layer deposition (ALD) processing; and
reducing contamination to the coating.
   These and other features and advantages should be apparent to those having ordinary skill in the art.

Accordingly, the present disclosure provides a vaporizing polymer spray deposition system and method. While the system and method have been disclosed showing certain features, the present disclosure may benefit any semiconductor process now known or developed in the future. While the preceding description shows and describes one or more embodiments, it will be understood by those skilled in the art that various changes in form and detail may be made therein without departing from the spirit and scope of the present disclosure. Therefore, the claims should be interpreted in a broad manner, consistent with the present disclosure.

1. A vaporizing spray deposition device comprising:
a processing chamber;
a fluid line configured to transfer a polymer fluid and solvent mixture; and
a spray head coupled to the fluid line proximate the processing chamber, the spray head configured to receive the polymer fluid and solvent mixture and atomize the polymer fluid and solvent mixture to emit it in a substantially vaporized form.

2. The vaporizing spray deposition device of claim 1, wherein the processing chamber comprises a base and sidewalls around the base, which extend away from the base toward the spray head.

3. The vaporizing spray deposition device of claim 2, wherein the processing chamber is configured to support a semiconductor wafer.

4. The vaporizing spray deposition device of claim 3, wherein the system is configured to provide a coating less than 100 Angstrom thick on the semiconductor wafer.

5. The vaporizing spray deposition device of claim 1, wherein the fluid line and the spray head are additionally configured to provide a solvent vapor, which is substantially free of the polymer fluid.

6. The vaporizing spray deposition device of claim 1, wherein the spray head is configured to atomize the polymer fluid and solvent mixture to have a droplet size range up to approximately 25 micrometers.

7. The vaporizing spray deposition device of claim 1, wherein the spray head is configured to emit the polymer fluid and solvent mixture at a rate range to form a coating at approximately 1 Angstrom per second to approximately 5 Angstrom per second on a surface proximate the spray head.

8. A photoresist spray deposition system comprising:
a processing chamber;
a fluid line configured to transfer a photoresist fluid;
a spray head coupled to the fluid line proximate the processing chamber, the spray head configured to receive the photoresist fluid and atomize the photoresist fluid to emit it in a substantially vaporized form; and
a heating device in the processing chamber, the heating device configured to provide a hard bake process to a semiconductor wafer receiving the photoresist fluid.

9. The photoresist spray deposition system of claim 8, wherein the processing chamber comprises a base and sidewalls around the base, which extend away from the base toward the spray head.

10. The photoresist spray deposition system of claim 9, wherein the heating device is configured to heat the photoresist fluid to a temperature range of approximately 100 C to approximately 200 C.

11. The photoresist spray deposition system of claim 10, wherein the heating device is configured to heat the photoresist fluid for a time range of approximately 1 second to approximately 60 seconds.

12. The photoresist spray deposition system of claim 8, wherein the fluid line and the spray head are additionally configured to provide a solvent vapor, which is substantially free of the photoresist fluid.

13. The photoresist spray deposition system of claim 8, wherein the spray head is configured to atomize the photoresist fluid to have a droplet size range up to approximately 25 micrometers.

14. The photoresist spray deposition system of claim 8, wherein the spray head is configured to emit the photoresist fluid to form a coating at a rate range of approximately 1 Angstrom per second to approximately 5 Angstrom per second on the semiconductor wafer.

15. A method of applying a thin film to a semiconductor wafer surface, the method comprising:
providing a vaporizing spray deposition system;
providing a semiconductor device wafer;
placing the semiconductor device wafer in proximity of an atomizing spray head on the vaporizing spray deposition system; and
atomizing a polymer/solvent solution toward the semiconductor device wafer, thereby depositing the solution on the semiconductor device wafer.

16. The method of claim 15, further comprising:
performing a hard bake process to the semiconductor device wafer after depositing the solution on the semiconductor device wafer.

17. The method of claim 16, wherein the hard bake process is performed at a temperature range of approximately 100 C to approximately 200 C for a time period of approximately 1 second to approximately 60 seconds.

18. The method of claim 15, wherein the solution deposited on the semiconductor device wafer is deposited to a thickness of less than approximately 100 angstroms on the semiconductor device wafer and includes PEMGA, PEMG, cyclehaxanol, EL, and combinations thereof.

19. The method of claim 15, further comprising:
applying a solvent spray trim process to the semiconductor device wafer after the depositing of the solution on the semiconductor device wafer, wherein a solvent for the process includes isopropyl alcohol, ethanol, ropanol, and combinations thereof.

20. The method of claim 15, including depositing the solution on the semiconductor device wafer at a rate of approximately 1 Angstrom/second to approximately 5 Angstrom/second.
